(19) United States
(12) Patent Application Publication
(10) Pub. No.: US 2021/0083360 A1
(43) Pub. Date: Mar. 18, 2021

(54) CHIPLESS RFID PRINTING METHODS

(71) Applicant: Hewlett-Packard Development Company, L.P., Spring, TX (US)

(72) Inventors: Ning Ge, Palo Alto, CA (US); Robert Ionesco, Palo Alto, CA (US); Steven J Simske, Ft. Collins, CO (US)

(73) Assignee: Hewlett-Packard Development Company, L.P., Spring, TX (US)

(21) Appl. No.: 16/618,854

(22) PCT Filed: Aug. 1, 2017
(86) PCT No.: PCT/US2017/044773

§ 371 Date: Dec. 3, 2019

(51) Int. Cl. H01Q 1/22; H05K 3/12; G06K 19/07

(52) U.S. Cl. CPC H01Q 1/2225; G06K 19/0723; H05K 3/125

(57) ABSTRACT

With the purpose of having RFID tags that are cheap to produce and that are environmentally friendly, it is disclosed a method and a system to manufacture chipless RFID tags. The method and system comprises printing a conductive track on a carbon-based substrate and selectively heating the substrate on the parts comprising the conductive track. The printing of the conductive track envisages using an ink comprising at least one of a metal carbide, a metal boride or a metal nitride.

### BACKGROUND

Radio frequency identification tags (RFID tags) are widely used in several fields for the identification of objects by wireless interrogation. RFID tags may be passive (without a power source) or active (with a power source).

Passive RFID tags can, in turn, be divided in two main groups, chipped or chipless. Chipped RFID tags comprise an antenna connected to a silicon chip being the chip adapted to draw enough power from an interrogation signal issued by an RFID reader to communicate with it wirelessly. Chipless RFID tags, on the other hand, have a simplified design by removing the use of chips while maintaining the ability to communicate with an interrogator through the use of antennas and/or resonators. Chipless RFID tags are easier to manufacture, much cheaper than chipped RFID tags and environmentally friendlier.

### BRIEF DESCRIPTION OF THE DRAWINGS

Examples will now be described, by way of non-limiting example only, with reference to the accompanying drawings, in which:

FIG. 1A shows a schematic view of the components of a chipless RFID tag according to an example.

FIG. 1B is an example of design or a conductive track of a chipless RFID tag.

FIG. 2 is a schematic view of an example of a manufacturing method of RFID tags.

FIG. 3 is a flow diagram of an example of a method of manufacturing RFID tags.

### DETAILED DESCRIPTION

RFID tags are widely used in several fields, however, the main drawback for a wider use is the manufacturing complexity and cost. Common RFID tags may be printed on a dielectric substrate by using inks containing silver which makes the manufacturing process too expensive for some applications. Also, the use of dielectric substrates and silver inks increase cost and complexity as special printers may be used. Furthermore, recycling of materials used in such RFID tags is uncommon.

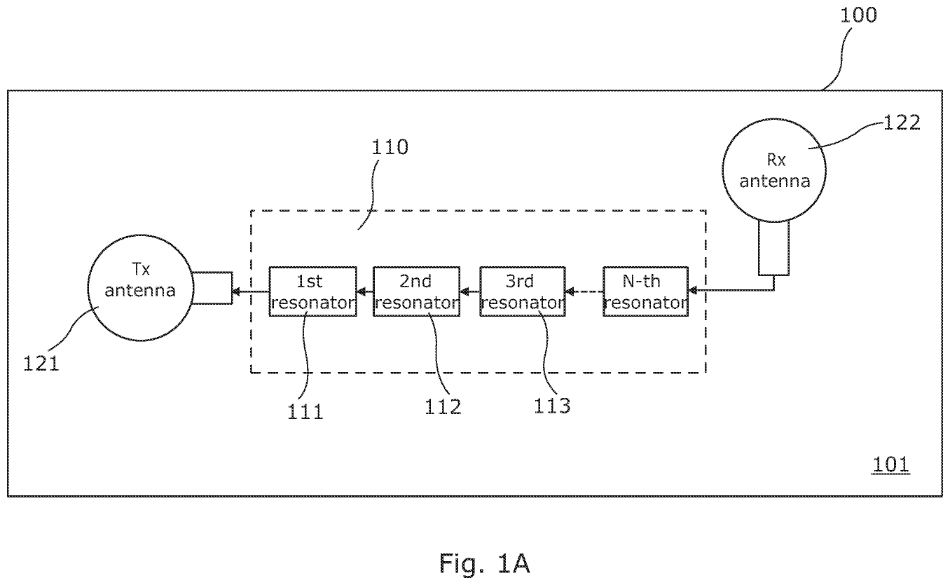

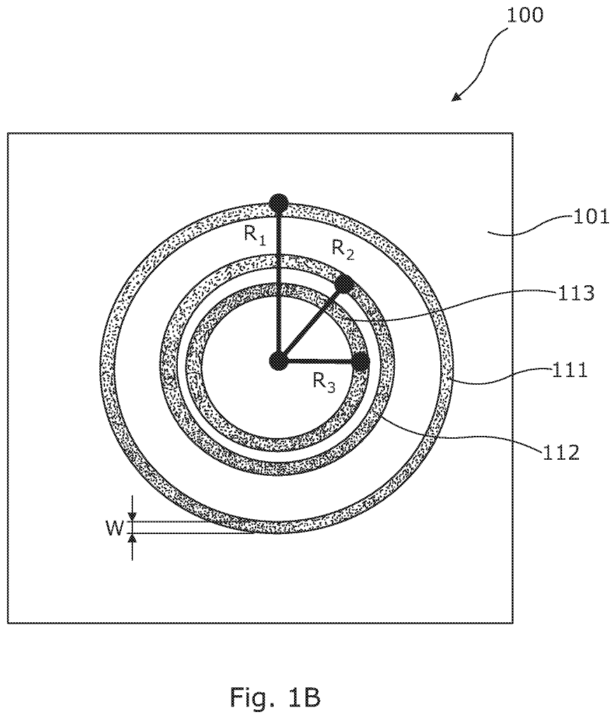

Referring to FIG. 1A an example of chipless RFID tag is shown. In particular, a chipless RFID tag 100 is shown that comprises a multiresonator 110, a receiving antenna 122 and a transmitting antenna 121. In an example, the receiving antenna 122 and the transmitting antenna 121 can be replaced by a single dipole antenna or, in a further example, lack an antenna as will be shown with reference to FIG. 1B. Also, the chipless RFID tag 100 of FIG. 1A may be printed on a carbon-based substrate 101 such as, e.g., paper by means of a metal carbide or metal nitride ink.

The multiresonator 100 may comprise a first resonator 111, a second resonator 112 and a third resonator 113; however, the quantity of resonators is not limited to three as any other number of resonators may be used depending on the particular application of the chipless RFID tag 100. In particular, the number of resonators may depend on the amount of information to be stored.

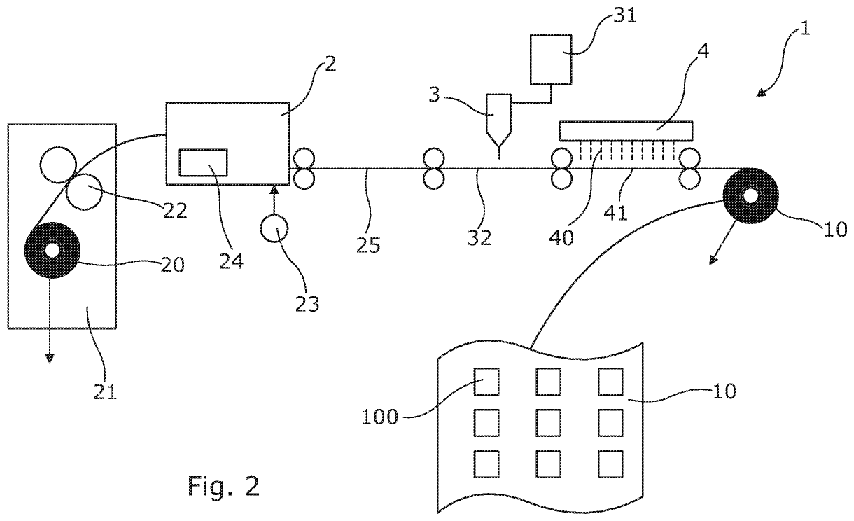

FIG. 1B shows an example of a chipless RFID tag 100 wherein comprising a multiresonator that has a first resonator 111, a second resonator 112 and a third resonator 113. In the example of FIG. 2B the resonators are conductive tracks forming circular rings with radius R₁, R₂ and R₃, respectively, and having a width w for all of the rings. As shown in the example of FIG. 1B, the circular rings may be concentric.

Circular resonators are known in the art and their structure is known to have a substantially constant electromagnetic response that is irrespective of the polarization of the incident wave. The resonance frequency for each of the rings is dependent on the width w of the conductive track and the radius of the ring. For example, for a ring with a radius between 9 and 4 mm with a width w of 0.5 mm, the resonance frequency may be approximately determined, for example, by the formula:

$${f}_{r} = \frac{c}{KR \sqrt{{ɛ}_{eff}}}$$

wherein fᵣ is the resonance frequency, R is the radius of the ring, c is the speed of light constant, and ε_{eff} the effective permittivity for the conductive track with a width w and K being a constant dependent mostly on the material (or materials) used for the conductive track and the substrate.

In summary, having a conductive track comprising several rings creates a specific electromagnetic signature in the frequency domain that is to be used for RFID reading/detection.

FIG. 2 shows an example of a manufacturing method for chipless RFID tags 100 using a chipless RFID printing system 1. In the example of FIG. 2 a cellulosic substrate is used, e.g., paper as a substrate for the chipless RFID tag 100. A feeder 21 may be included wherein a paper roll 20 is loaded is fed to a printer 2 by means of a feeding roller 22.

The printer 2 may comprise a printer controller 24 that may be used for controlling the printing processes: for example, the amount of paper to be fed by the feeding roller 22 and its speed. Also, the printer controller 24 may be used to control at least one printhead as to print conductive tracks on the carbon-based substrate, in this example, the paper roll 20.

The conductive tracks may be printed by using a particular type of ink, e.g., carbide metal, boride metal or nitride metal inks. Examples of carbide metal inks can be: MgCNi₃, La₂C₃, Y₂C₃, Mo₃C₂, LaNiC₂, Mo₃Al₂C, SiC, TiC, VC, WC, W₂C, ZrC, MOC, NbC or any combination between them. Examples of nitride metal inks can be: TiN, VN, BN, AlN, CrN, MgSiN₂. These inks may be stored in an ink supply 23 fluidly connected to the printer 2.

Metal carbide and metal nitride inks have specific properties that allow the printing of RFID tags 100 on carbon or carbon fiber-based substrates, like paper. In particular, metal carbides and metal nitrides are good electric conductors and have the particularity of having refractory properties which protects the substrate upon the presence of a heating source. Paper electronics are normally very susceptible to heating and the use of metal carbides and metal nitride as inks not only reduces the cost of printing (in comparison to expensive silver-based inks) but also, the refractory properties protect at some extent the substrate in further heating processes.

Paper is a thin material produced by pressing together moist fibers of cellulose pulp derived from wood, rags or grasses, and drying them into flexible sheets. It is a versatile material with many uses, including writing, printing, packaging, cleaning, and a number of industrial and construction processes. Furthermore, it is carbon-based substrates which are a source of carbon that will help to provide carbon to be sintered or carbonized with the ink solution as well as certain amounts of graphene, carbide, etc. to be mixed with metal carbide for the enhancement of the conductivity during a subsequent heating process. In particular, soot is known to include buckminsterfullerene which is conductive under some reactions with carbon-based substrates. The buckminsterfullerene may provide the conductive sections of the substrate with improved conductivity.

The printer 2 for carrying out the printing of the conductive track may be any type of ink-based printer; for example, an inkjet printer or an offset printer like for example, a web press.

After printing, a printed substrate 25 is obtained. The printed substrate 25 is subsequently subject to a heating treatment by means of a heater, in particular, a laser source 3 configured to selectively heat at least the parts of the printed substrate that comprise conductive tracks. The laser 3 may be connected to peripheral devices 31 such as a controller to control the position and power of the laser or a CCD camera to determine the parts of the substrate comprising conductive tracks.

Once the printed substrate 25 is heated, a conductive substrate 32 is obtained wherein, at this stage, the substrate already comprises a chipless RFD tag 100.

In another example, the printer 2 may also comprise a printhead to be fed with dielectric ink in order to print with non-conductive material, at least, the surroundings of the conductive track or, alternatively, the complementary parts of the substrate, i.e., portions of the substrate that do not comprise conductive tracks printed. Also, the dielectric ink may be activated by the laser 3, so that the laser may selectively heat, not only the conductive tracks, but also the portions of the substrate comprising the dielectric ink.

Even though the conductive substrate 32 already comprises a chipless RFID tag 100 that would work, in some cases, post-processing of, the conductive substrate 32 may be performed. The post-processing can be performed in a post-processing unit 4 wherein the conductive substrate can be subject, for example, to a cooling process by depositing sprinkling droplets 40 of water over the substrate. Alternatively, the postprocessing may comprise depositing a top sealed layer for surface protection, such as an overprint coating.

As a result, a finished substrate 41 obtained and r ray be stored again as roll of chipless RFID tags 10.

Overprint coatings may be applied to the conductive substrate 32 for different purposes. These coatings may be, for example, a dielectric coating, oleoresins, or binding coatings (e.g., styneric or acrylic coatings). In an example, the overprint coating may be used for increasing the conductivity on the conductive tracks, for example, by using nanographite or nanocellulose coatings which, in addition to conductivity, proves the water retention of the finished substrate 41.

The roll of chipless RFID tags 10 may comprise several RFID tags that may each comprise a different configuration of conductive track, such as different configurations either in width w of the tracks or in the pattern used.

It is to be noted that, even though in the example of FIG. 2 the paper feeder, the printer, the heater and the prose-processing unit are shown as separate devices, they could also be enclosed in a single device and share some elements; for example, by using a shared controller.

In essence, FIG. 2 shows a process wherein a conductive track is first printed by means of a metal boride, a metal nitride, a metal carbide or a combination between at least two of them on a carbon-based substrate. Then, a sintering, annealing or curing of the ink is performed by means, e.g., of a laser to selectively heat the portions of the substrate comprising the conductive track. Finally, an optional step of post-processing is performed, e.g., by coating the substrate.

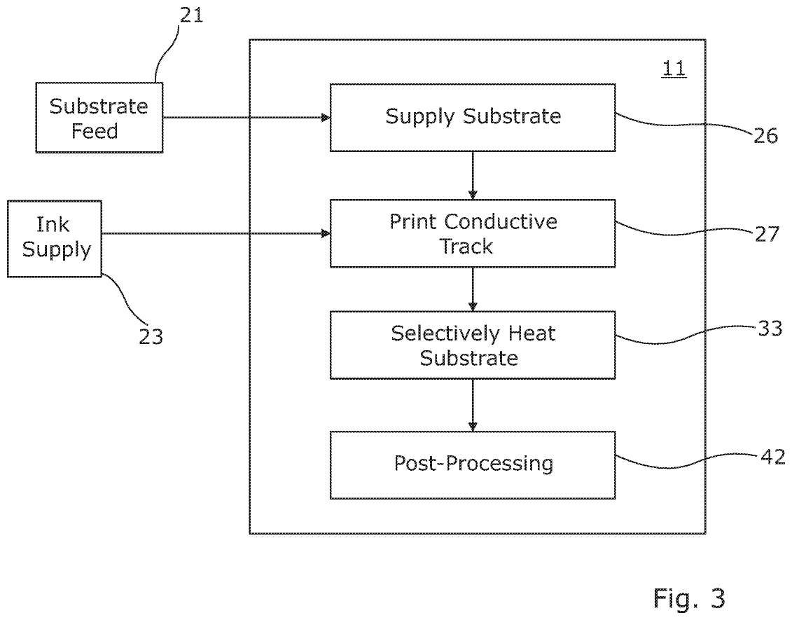

FIG. 3 shows a flowchart of the chipless RFID tag printing process. In the example of FIG. 3 a shared controller 11 is used to control the process. In particular, a substrate is received from a feeder 21 to a printer and the shared controller controls the supply of substrate 26 to the printer 2.

Once the substrate is located on the printer 2 the printer prints a conductive track 27 on the substrate. In particular, the printing is made by use of a metal carbide or metal nitride ink stored in the ink supply 23. Also, the substrate may be carbon-based substrate, e.g., cellulosic substrate, like paper or cardboard. In case the substrate is cardboard, the cardboard may be a box and the chipless RFID tag 100 may be printed directly on the cardboard that is to form the box, thereby reducing the cost of boxes, e.g., in supply chains wherein boxes and RAD tags are normally printed separately.

Subsequently, heat is applied 33, at least, on the parts of the substrate comprising the conductive track. The heat may be selectively applied on the parts comprising the conductive, track by using a laser controlled to heat only the parts comprising the conductive track. The identification of which parts comprise the conductive track may be performed, e.g., by detecting such parts by using a camera.

Finally, the method comprises a post-processing 42 of the substrate. This postprocessing may be, e.g., cooling the paper by air blowing or droplet sprinkling. Also, the post processing may comprise depositing a protective layer over the chipless RFID tag.

In essence, it is disclosed a method of manufacturing chipless RFID tag comprising:
printing a conductive track on a carbon-based substrate; and
selectively heating the substrate on the parts comprising the conductive track;
   wherein the printing of the conductive track comprises using an ink comprising at least one of a metal carbide, a metal boride or a metal nitride.

The selective heating of the substrate may be performed by directing a laser towards the conductive track

As for the substrate, the carbon-based substrate may be a cellulosic substrate, e.g., paper or cardboard, wherein cardboard is especially useful as the RFID tags may be printed directly on a cardboard packaging.

In an example, the conductive track comprises an antenna. The antenna may be a passive antenna and, in an example, may comprise a receiving antenna and a transmitting antenna. Alternatively a single dipole antenna may be used.

In an example, the conductive track comprise resonator.

In a further example, the inks envisaged may be metal carbide inks comprising a material selected from MgCNi3, La2C3, Y2C3, Mo3C2, LaNiC2, Mo3Al2C, SiC, TiC, VC, WC, W2C, ZrC, MoC, or NbC, Also, the inks may be metal nitride inks comprising a material selected from: TiN, VN, BN, AlN, CrN or MgSiN2.

Furthermore, it is envisaged a post-processing of the RFID tag, in an example, this post-processing may comprise adding a top layer surface on the substrate, at least, over the conductive track. This post-processing may be selected to improve water retention, improve water repelling, increase the resistance to tearing of the substrate and/or improve the conductivity of the conductive tracks.

Additionally, it is disclosed a chipless RHO tag manufacturing system comprising:

an ink-based printer a selectively heating mechanism wherein the printer is to use an ink comprising at least one of a metal carbide, a metal bonds or a metal nitride to print a conductive track on a carbon-based substrate and the selectively heating mechanism is to selectively heat the portions of the substrate comprising the conductive track.

As mentioned above, examples of metal carbide inks to be used by the system may comprise a material selected from: Ni3, La2C3, Y2C3, Mo3C2, LaNiC2, Mo3Al2C, SIC, TiC, VC, WC, W2C, ZrC, MoC, or NbC. Alternatively, metal nitride inks are envisaged wherein the inks may comprise a material selected from: TiN, VN, BN, AlN, CrN or MgSiN2.

In an example, the conductive track comprises an antenna. This antenna may be a unipole or dipole antenna.

In a further a pie, the conductive track comprises a resonator.

Furthermore, the printer may be any type of ink-based printer; the printer may be an offset printer, like a press.

1. A method of manufacturing of a chipless RFID tag comprising:
a. printing a conductive track on a carbon-based substrate; and
b. selectively heating the substrate on the parts comprising the conductive track;
wherein the printing of the conductive track comprises using an ink comprising at least one of a metal carbide, a metal boride or a metal nitride.

2. The method of claim 1, wherein the selective heating of the substrate is performed by directing a laser towards the conductive track.

3. The method of claim 1, wherein the substrate is substrate.

4. The method of claim 3, wherein the substrate is paper.

5. The method of claim 1, wherein the conductive track comprises a passive antenna.

6. The method of claim 1, wherein the conductive track comprises a resonator.

7. The method of claim 1, wherein the ink is a metal carbide comprising a material selected from MgCNi₃, La₂C₃, Y₂C₃, MO₃C₂, LaNiC₂, Mo₃Al₂C, SiC, TiC, VC, WC, W₂C, ZrC, MoC, or NbC.

8. The method of claim 1, wherein the ink is a metal nitride comprising a material selected from: TiN, VN, BN, AlN, CrN or MgSiN₂.

9. The method of claim 1, further comprising adding a top layer surface on the substrate over the conductive track.

10. A chipless RFID ag manufacturing system comprising:
an ink-based printer
a selectively heating mechanism
wherein the printer is to use an ink comprising at least one of a metal carbide, a metal boride or a metal nitride to print a conductive track on a carbon-based substrate and wherein the selectively heating mechanism is to selectively heat the portions of the substrate comprising the conductive track.

11. The system of claim 10, wherein the ink is a metal carbide that comprises a material selected from MgCNi₃, La₂C₃, Y₂C₃, Mo₃C₂, LaNiC₂, Mo₃Al₂C, SiC TiC, VC, WC, W2C, ZrC, MoC, or NbC.

12. The system of claim 10, wherein the ink is a metal nitride that comprises a material selected from: TiN, VN, BN, AlN, CrN or MgSiN₂.

13. The system of claim 10, wherein the conductive track comprises an antenna.

14. The system of claim 10, wherein the conductive track comprises a resonator.

15. The system of claim 10, wherein the printer is a press.
